(19) United States
(12) Patent Application Publication
(10) Pub. No.: US 2006/0146624 A1
(43) Pub. Date: Jul. 6, 2006

(54) Current folding sense amplifier

(75) Inventors: Yoram Betser, Mazkeret Batya (IL); Yair Sofer, Tel- Aviv (IL)

Correspondence Address: TIAJOLOFF & KELLY, CHRYSLER BUILDING, 37TH FL, 405 LEXINGTON AVE, NEW YORK, NY, 10174, US

(73) Assignee: Saifun Semiconductors, Ltd., Netanya (IL)

(21) Appl. No.: 11/291,302

(22) Filed: Dec. 1, 2005

Related U.S. Application Data
(60) Provisional application No. 60/632,199, filed on Dec. 2, 2004.

(51) Int. Cl. G11C 7/00

(52) U.S. Cl. 365/205

(57) ABSTRACT

A method for sensing logical content stored in a memory cell, the method including inputting an input cell current of a selected array cell of a memory array to an input stage, and folding the input cell current and using it to discharge an input of a latch, the latch providing an output digital signal indicative of a logical content stored in the selected array cell.

### FIELD OF THE INVENTION

This invention relates generally to semiconductor memories, and more particularly to methods and circuitry for sensing logical states of data stored in memories.

### BACKGROUND OF THE INVENTION

As is well known in the art, a memory cell in a memory device, such as but not limited to, random access memory (RAM), read-only memory (ROM) and non-volatile memory (NVM), can be configured to provide an electrical output signal during a read operation. A sense amplifier is coupled to receive the electrical output signal, and in response, provide a data output signal representative of the logic state of the data stored by the memory cell.

In general, sense amplifiers determine the logical value stored in a memory cell by comparing the electrical output signal (voltage or current) provided by the cell with a threshold value (voltage or current). If the electrical output signal exceeds the threshold value, the sense amplifier provides a data output signal having a first logic value (e.g., logic “1”), thereby indicating that the memory cell is in a first logic state (e.g., erased). Conversely, if the electrical output signal is less than the threshold value, the sense amplifier provides a data output signal having a second logic value (e.g., logic “0”), thereby indicating that the memory cell is in a second logic state (e.g., programmed).

The threshold value is typically set at a level that is between the expected electrical output signal for a programmed state of a memory cell and the expected electrical output signal for an erased state of a memory cell. It is desirable to set the threshold value at a level that is sufficiently far from both expected levels, so that noise on the electrical output signal will not cause false results.

In a virtual ground array, the readout of a cell may depend on the state of its neighbor cells. A change in the state of the neighbors of a cell may affect the cell readout reliability. This undesired effect is known in the art as the “neighbor effect”.

The neighbor effect will be better understood by reference to FIG. 1 which is a block diagram of NVM cells in a virtual ground array. Memory cell MC 3 in FIG. 1 is verified to be in a specific state, e.g., programmed or erased. When memory cell MC 3 is read, the signal developed at the reading node, for example, either the drain side or the source side of the cell, has two components: the current of the cell itself, and the current flowing to or from neighbor cells, depending if cell MC 3 is read from the source or from the drain. Neighbor cells may share the same word line of the cell being read and may be connected, either directly or through other cells, to the reading node. For example, in the configuration of FIG. 1, cells MC 2 and MC 4 are adjacent to cell MC 3. When one or more of the neighbor cells changes from an erased state to a programmed state or vice versa, the read-out current from MC 3 may exhibit a different signal at the reading node, because the current component of its neighbor cells has changed.

Thus, for example, if cell MC 3 is read out from its drain side (shown in FIG. 1) then after the state of MC 2 is changed from an erased state to a programmed state, its current “contribution” to the read-out current of MC 3 may change, and therefore, the read-out for MC 3 may exhibit a different signal at the reading node. A similar effect may happen, for example, after the state of MC 4 is likewise changed for the case of source-side read. If cells further along the same word line change their state (e.g. MC 1, MC 5, MC 6, etc., not shown in FIG. 1) they may also affect the readout of MC 3. The influence on MC 3 of such changes in the states of cells MC 1, MC 2, MC 4, MC 5 and MC 6 may not necessarily be of equal magnitude and may depend on the readout scheme, i.e. drain-side read or source-side read.

A memory cell, such as MC 3 in FIG. 1, may be read from its drain side or its source side, i.e. the cell current or voltage signal may be sensed or derived from either its drain or source terminals. The neighbor effect may reduce the margin of a memory cell causing it to be read incorrectly in either of drain-side or source-side readout schemes.

Methods for reducing the neighbor effect in reading data in a non-volatile memory array have been proposed, such as that described in U.S. patent application Ser. No. 20050232024 to Atir and Dadashev, assigned to the present assignee of the present application.

### SUMMARY OF THE INVENTION

The present invention seeks to provide novel sensing scheme for current signals generated from the source of a memory cell. The scheme involves folding of a memory cell current into a sense amplifier, generating an internal signal inside the sense-amplifier, which after a sufficient sensing time is compared to a reference signal. A logical signal based on the difference between the memory cell signal and the reference signal is then obtained, as described in detail herein below. One advantage of the current invention is that it provides a mean for reducing the neighbor effect of a virtual ground array as explained in detail hereinbelow. The devices and methods may be used for source sensing of memory cells, in particular for NVM memory applications.

There is thus provided in accordance with an embodiment of the invention a method for sensing logical content stored in a memory cell, the method including inputting an input cell current of a selected array cell of a memory array to an input stage, and folding the input cell current and using it to discharge an input of a latch, the latch providing an output digital signal indicative of a logical content stored in the selected array cell.

In accordance with an embodiment of the invention folding the input cell current is carried out by an NMOS current mirror using an NMOS source-follower in the input stage.

Further in accordance with an embodiment of the invention the method includes inputting bias voltages to the input stage so as to provide a constant current signal at drains of the NMOS current mirror, the current signal being defined by a folding ratio associated with the NMOS current mirror.

In accordance with an embodiment of the invention the method includes inputting a current signal cmi and a reference signal tref to the input stage, the input stage generating voltages V_latch_in and V_latch_in_b corresponding to the current signal cmi and the reference signal tref, respectively, the voltages being used to discharge the input of the latch. The current signal cmi and reference signal tref define a differential current signal ‘I_cmi-I_tref′, and the voltages V_latch_in and V_latch_in_b define a differential voltage signal ‘V_latch_in-V_latch_in_b′, wherein the differential voltage signal may be proportional to the differential current signal.

Further in accordance with an embodiment of the invention the latch creates a logical differential signal based on the differential voltage signal, the logical differential signal being latched by a digital latching stage as a constant output latched signal until another latch signal is issued.

There is also provided in accordance with an embodiment of the invention a system for sensing logical content stored in a memory cell, the system including a first stage including an analog input stage that receives an input cell current of a selected array cell of a memory array, the input stage including a current mirror operative to fold the input cell current, a second stage including an analog latch stage which generates a digital signal out of an analog signal coming from the input stage, and a third stage including a digital latching stage operative to output a digital signal indicative of a logical content stored in the selected array cell.

In accordance with an embodiment of the invention the input stage includes an NMOS current mirror using an NMOS source-follower. The second stage may include a cross-coupled latch, and the digital latching stage may include a set-reset flip flop.

In accordance with an embodiment of the invention the first, second and third stages are part of a sense amplifier device. Alternatively, in accordance with another embodiment of the invention, the first and second stages are part of a sense amplifier device, and the third stage is external to the sense amplifier device.

### BRIEF DESCRIPTION OF THE DRAWINGS

The present invention will be understood and appreciated more fully from the following detailed description taken in conjunction with the drawings in which:

FIG. 1 is a simplified block diagram demonstrating the neighbor effect in non-volatile memory (NVM) cells in a virtual ground array (VGA);

FIG. 2 is a simplified block diagram of sensing memory cells in a non-volatile memory array in accordance with an embodiment of the invention;

FIG. 3 is a simplified block diagram of a sense amplifier for the system of FIG. 2, in accordance with an embodiment of the invention;

FIG. 4A is a more detailed circuit diagram of an input stage of the sense amplifier of FIG. 3, in accordance with an embodiment of the invention;

FIG. 4B is a more detailed circuit diagram of a cross-coupled latch and flip-flop of the sense amplifier of FIG. 3, in accordance with an embodiment of the invention;

FIG. 5A is a simplified graphical illustration of waveforms of signals of the sensing system of FIGS. 2-4B, in accordance with an embodiment of the present invention;

FIG. 5B is a simplified graphical illustration of a digital sensing sequence, which is part of a typical sensing scheme, and

FIG. 6 is a simplified graphical illustration of waveforms of signals of a prior art memory source sensing system, wherein signals cmi and tref are generated during the sensing period.

### DETAILED DESCRIPTION OF EMBODIMENTS

In the following detailed description, numerous specific details are set forth in order to provide a thorough understanding of the invention. However, it will be understood by those of ordinary skill in the art that the present invention may be practiced without these specific details. In other instances, well-known methods and procedures have not been described in details so as not to obscure the present invention.

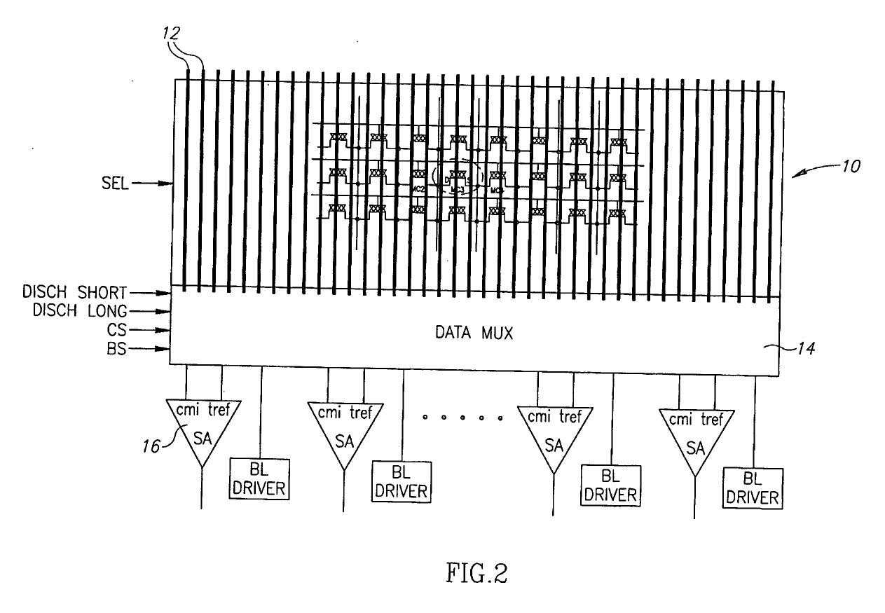

Reference is now made to FIG. 2, which illustrates a basic block diagram of memory sensing, in accordance with an embodiment of the present invention. Cells of a memory array 10 generate current signals, which are carried through global bit lines 12 (GBL's) into a data MUX 14. The data MUX 14 transfers the current signals to inputs cmi of sense amplifiers 16. A reference signal, not shown in FIG. 2, is carried to another input, tref, of sense amplifiers 16. This signal may or may not be a current signal, which may or may not be generated by a matched memory cell (MC) used as a reference cell.

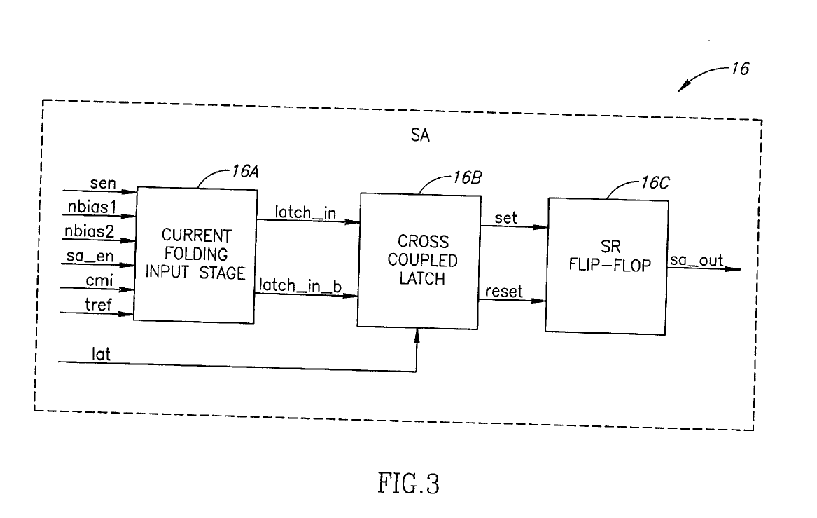

Reference is now made to FIG. 3, which illustrates a simplified block diagram of sense amplifier (SA) 16. Sense amplifier 16 may contain three stages. A first stage 16A, also referred to as input stage 16A, may be an analog input stage that receives the MC input signal cmi and the reference signal tref. A second stage 16B may be an analog latch stage which generates a digital signal out of the analog signal coming from the first stage. The second stage 16B may be, but is not necessarily, a cross-coupled latch. A third stage 16C may be a digital latching stage (a set-reset flip flop (SR-FF) is shown in FIG. 3, but the invention is not limited to this and may be carried out with any other latching element). The digital latching stage 16C is shown in the non-limiting illustrated embodiment as part of the SA block, but the invention is not limited to this and the digital latching stage 16C may alternatively be located elsewhere in a general latching area.

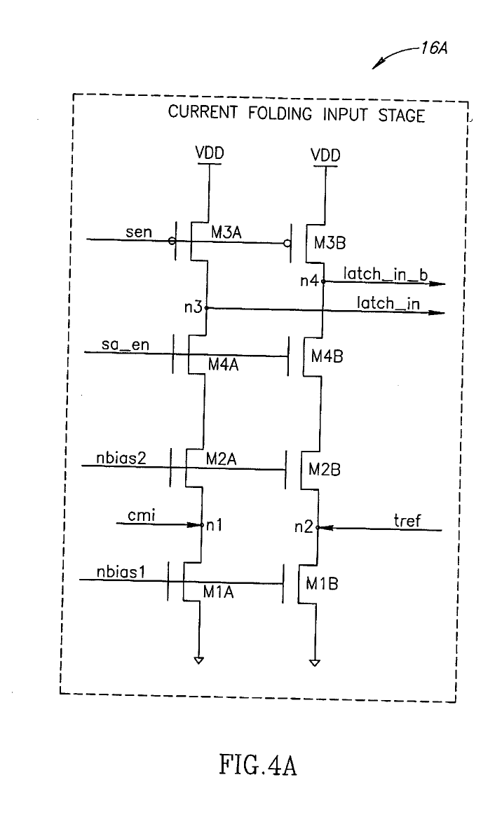

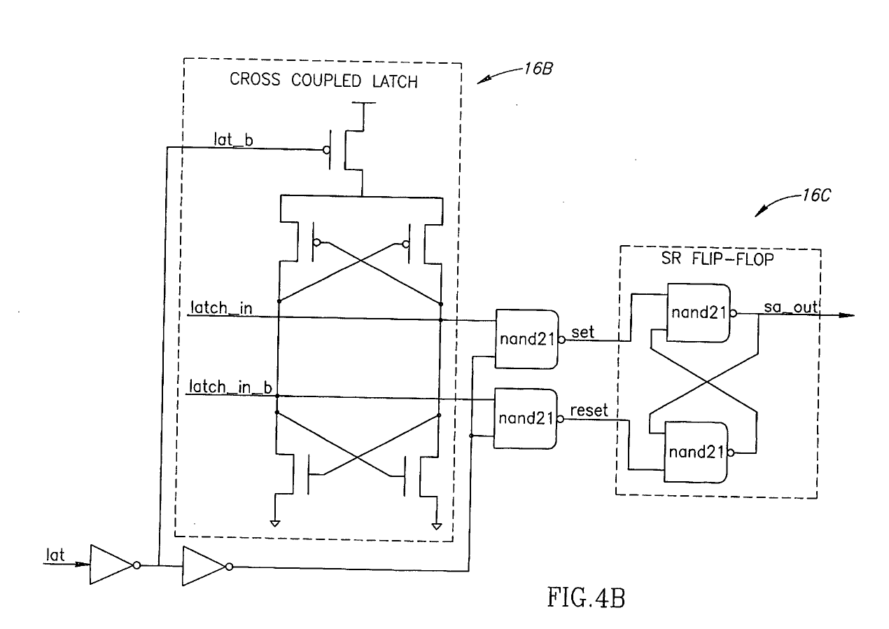

Reference is now made to FIG. 4A, which illustrates the input stage 16A of sense amplifier 16 in more detail. In the non-limiting illustrated embodiment, it is assumed that tref is a current based signal, but as mentioned above, the invention is not limited to this specific assumption. The current folding input stage 16A of sense amplifier 16 may include a pair of NMOS (n-channel metal oxide semiconductor) transistors M1A and M1B that serve as active resistors and may be operated in a common gate configuration. NMOS transistors M1A and M1B may receive a voltage signal ‘nbias1’. Specifically, in the non-limiting illustrated embodiment, voltage signal ‘nbias1’ is input to a gate of M1A, a source and bulk of M1A are connected to ground (GND), and a drain of M1A is connected at a circuit node n1 to input cmi. The gates of NMOS transistors M1A and M1B are connected to each other. A source and bulk of M1B are connected to GND, and a drain of M1B is connected at a circuit node n2 to reference signal tref. These transistors serve as active resistors.

The current folding input stage 16A of sense amplifier 16 may further include a pair of NMOS transistors M2A and M2B that receive a voltage signal ‘nbias2’. These NMOS transistors may also be operated in a common gate configuration. Specifically, in the non-limiting illustrated embodiment, voltage signal ‘nbias2’ is input to a gate of M2A, a source and bulk of M2A are connected at circuit node n1 to input cmi, and a drain of M2A is connected to a source of an NMOS transistor M4A (enable transistor described below). The gates of NMOS transistors M2A and M2B are connected to each other. A source and bulk of M2B are connected at circuit node n2 to reference signal tref, and a drain of M2B is connected to a source of an NMOS transistor M4B (enable transistor described below).

NMOS transistor pairs M1A and M1B and M2A and M2B are current mirrors. A current mirror is defined as a circuit element or portion of a circuit that receives an input current and outputs the same input current or a multiple thereof. NMOS transistors M2A and M2B together with NMOS transistors M1A and M1B may provide a constant current signal 10 at the drain of NMOS transistors M1A and M1B. A typical value of I0 would be 10 μA, and a typical value for cmi/tref voltage (at the drain of NMOS transistors M1A and M1B, respectively) would be 100 mV. The signals ‘nbias1’ and ‘nbias2’ may be generated from a global biasing circuit, well known in the art and not described here. This circuit can be designed such that the current signal I0 and the drain voltage of NMOS transistors M1A and M1B are kept constant for a set of temperature ranges, voltage supply VDD ranges and process corners.

The current folding input stage 16A of sense amplifier 16 may further include a pair of NMOS transistors M4A and M4B, which may serve as enabling devices for the circuit, receiving an input signal sa_en (sense amplifier enable). Specifically, in the non-limiting illustrated embodiment, input signal sa_en is input to a gate of M4A, and the gates of M4A and M4B are connected to each other. A drain of M4A is connected at a circuit node n3 to a drain of a PMOS transistor M3A (pre-charge device described below) and to signal latch_in. A drain of M4B is connected at a circuit node n4 to a drain of a PMOS transistor M3B (pre-charge device described below) and to signal latch_in_b.

The current folding input stage 16A of sense amplifier 16 may further include a pair of PMOS transistors M3A and M3B, which may be used as pre-charge devices for the nodes ‘latch_in’ and ‘latch_in_b’. Specifically, in the non-limiting illustrated embodiment, an input signal sen is input to a gate of M3A, and the gates of M3A and M3B are connected to each other. As mentioned above, the drain of M3A is connected at circuit node n3 to signal latch_in, and the drain of M3B is connected at circuit node n4 to signal latch_in_b. The sources of PMOS transistors M3A and M3B may be connected to supply voltage VDD.

Reference is now made to FIG. 4B, which illustrates a non-limiting example of circuitry for the second stage 16B, which as mentioned above, may be, but is not necessarily, a cross-coupled latch. The circuitry is well known in the art, and does not require further description for the skilled artisan. The cross-coupled latch generates a digital signal out of the analog signal coming from the first stage. As mentioned before, the third stage 16C may be a set-reset flip flop (SR-FF), but the invention is not limited to this and may be carried out with any other latching element. Again, the circuitry is well known in the art, and does not require further description for the skilled artisan.

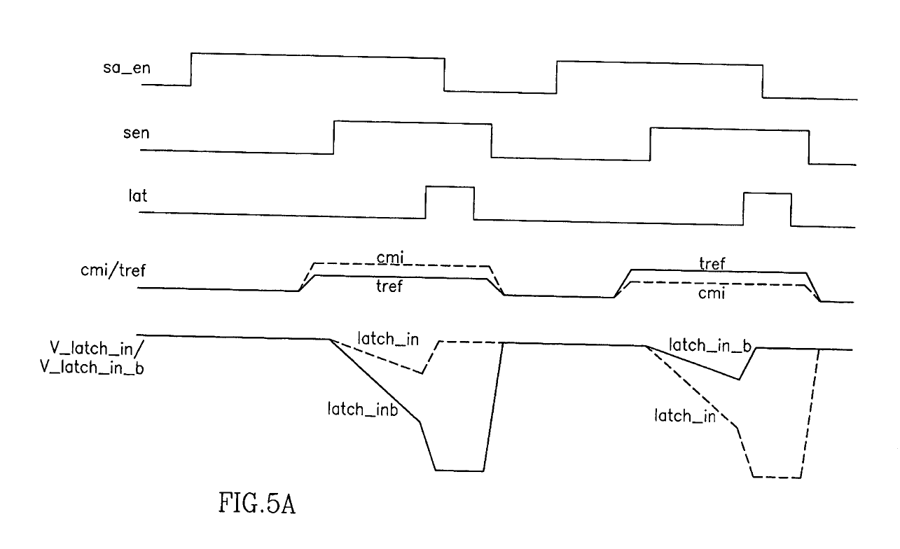

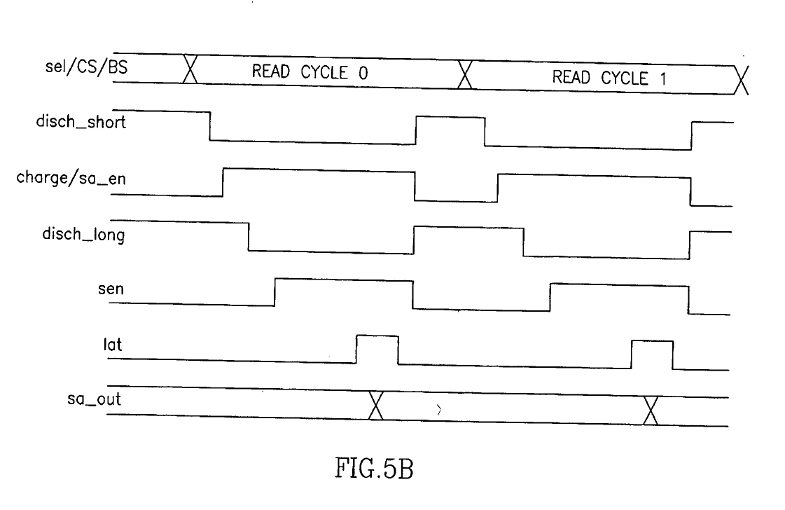

The operating principle of the input stage 16A shown in FIG. 4A may be better understood with reference to FIG. 5A, which is a graphical illustration of waveforms of signals of the sensing system of FIGS. 2-4B, in accordance with an embodiment of the present invention (x-axis is time).

The starting point of operation is when the voltages ‘nbias1’ and nbias2’ are ready, input sa_en=logical ‘1’, input sen=logical ‘0’ and input lat=logical ‘0’. Once a current signal I_cmi is generated at the node cmi (i.e., node n1), the voltage of cmi will rise. By proper sizing of NMOS transistors M1A and M2A, and proper biasing of voltages ‘nbias1’ and ‘nbias2’, the voltage rise would be very small (approximately, without limitation, in the range of 10 mV-20 mV). In this manner, the drain current of NMOS transistor M1A would almost remain constant, and as well known in the art, the source/drain current of NMOS transistor M2A would reduce proportionally to the value of the input current I_cmi.

The drain current of NMOS transistor M2A is thus given by: I0-k*I_cmi. The parameter ‘k’ is called the folding ratio, where k=1 is the ideal case. Typical values for ‘k’ may be in the range of 0.7-0.9. Once the drain current of NMOS transistor M2A stabilizes, the signal sen rises to a logical ‘1’, thus stopping the current flow from the drain of PMOS transistor M3A into the node ‘latch_in’ (i.e., via node n3). However, the drain current of NMOS transistor M4A (which is equal to the drain current of NMOS transistor M2A, namely I0-k*I_cmi) discharges the node ‘latch_in’ creating a voltage signal, ‘V_latch_in’ (FIG. 5A), which is proportional to the MC current signal I_cmi and the capacitance associated with the node ‘latch_in’.

The same event sequence described above is also true for I_tref, M1B, M2B, M3B and M4B. Specifically, once a reference signal I_tref, is generated at the node tref (i.e., node n2), the voltage of tref will rise. By proper sizing of NMOS transistors M1B and M2B, and proper biasing of voltages ‘nbias1’ and ‘nbias2’, the voltage rise would be very small (approximately, without limitation, in the range of ˜10 mV-20 mV). In this manner, the drain current of NMOS transistor M1B would almost remain constant, and as well known in the art, the source/drain current of NMOS transistor M2B would reduce proportionally to the value of the input current I_tref. The drain current of NMOS transistor M2B is thus given by: I0-k₂*I_tref wherein k₂ is some folding ratio (not necessarily=k above). Once the drain current of NMOS transistor M2B stabilizes, the signal sen rises to a logical ‘1’, thus stopping the current flow from the drain of PMOS transistor M3B into the node ‘latch_in_b’ (i.e., via node n4). However, the drain current of NMOS transistor M4B (which is equal to the drain current of NMOS transistor M2B, namely I0-k₂*I_tref) discharges the node ‘latch_in_b’ creating a voltage signal, ‘V_latch_in_b’ (FIG. 5A), which is proportional to the reference current I_tref and the capacitance associated with the node ‘latch_in_b’.

Accordingly, a voltage signal, ‘V_latch_in_b’ is generated at the node ‘latch_in_b’ which is proportional to the reference current I_tref and the capacitance associated with node ‘latch_in_b’. If the capacitances associated with nodes ‘latch_in’ and ‘latch_in_b’ (FIG. 4A) are of equal value, the differential voltage signal ‘V_latch_in-V_{—}latch_in_b’ is proportional to the differential current signal ‘I_cmi-I_tref’. In FIG. 5A, two read cycles are shown, where in the first one (leftmost in the diagram) the current I_cmi is larger than I_tref, and in the second one (rightmost in the diagram) the current I_cmi is smaller than I_tref.

The rise of the signal ‘lat’ (FIG. 5A), enables the positive feedback cross-coupled latch 16B (FIG. 4B), which in turn creates a logical differential signal at the output of the analog latch, based on the analog differential signal ‘V_latch_in-V_latch_inb’. The logical differential signal output by cross-coupled latch 16B is latched by the digital latching stage 16C (e.g., SR-FF in FIG. 4B), which keeps the latched signal at its output sa_out until another ‘lat’ signal is issued. It is noted that the use of the digital latching element 16C, such as SR-FF, is preferred, because the fall of the lat signal may destroy the differential voltage signal, ‘V_latch_in-V_latch_in_b’, as can be seen from FIG. 5A.

Reference is now made to FIG. 5B, which illustrates a simplified timing diagram of a digital sensing sequence, which is part of a typical sensing scheme. The sequence may involve address stabilization (sel, CS, BS), disabling of discharge of the global bit lines, charging of the drain side of the MC (charge) and sense amplifier enabling, sensing period (sen), latching period (lat) and stabilization of the sense amplifier output. Such a sequence may follow typical sensing sequences known in the art, and which do not require further description for the skilled artisan.

Advantages of the sensing method and architecture described above include, but are note limited to:

1. Efficient Gain/Area/Power Tradeoff.

Prior art sense amplifiers for a close-to-ground source-sensing scheme typically involve one of three options: PMOS input differential stage, PMOS level shifting stage, and AC coupled stage. There are disadvantages to the prior art sense amplifiers. The PMOS differential stage has low gain and thus relatively large random offset due to process variations. The PMOS level shifting stage sinks extra power and also has a large random offset. The AC coupled stage takes up a relatively large area.

In contrast, the current folding scheme of the present invention uses an NMOS differential input stage, which has high gain and thus relatively low random offset. Thus, one reason for the large gain of the method of the present invention is the use of NMOS devices rather than PMOS devices. Another reason is the voltage signals ‘V_latch_in’ and ‘V_latch_in_b’ are generated across relatively small capacitances associated with the nodes latch_in and latch_in_b, respectively. In a typical source sensing scheme, the signal is generated across the global bit line capacitance with is approximately ten times larger. In terms of area consumed, the current folding sensing scheme of the present invention is relatively small and thus enables using a large amount of sense amplifiers for fast parallel reading.

2. Reduction of Neighbor Effect in VGA (Virtual Ground Array) Topologies.

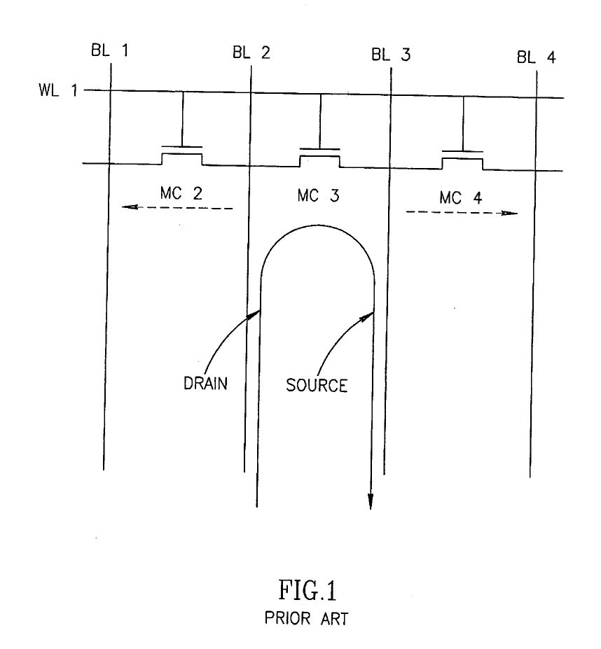

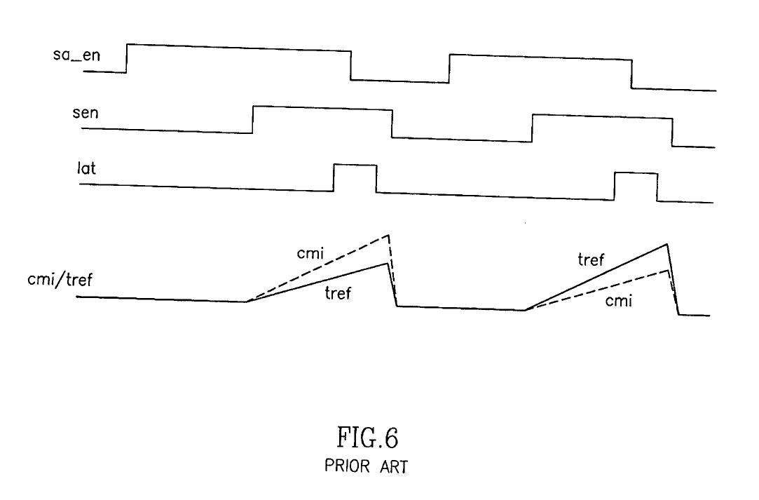

The current folding sensing scheme of the present invention, when applied to VGA topologies can effectively reduce the neighbor effect, which was described in the background. The reduction of the neighbor effect may be understood by comparing FIGS. 1, 5A and 6, to which reference is now made. In FIG. 6, a prior art source-sensing scheme simple time diagram is illustrated, wherein the signals cmi and tref are generated during the sensing period.

Signals cmi and tref are typically linearly rising voltage signals. Accordingly, if for example, cmi is connected to the source of memory cell MC3 in FIG. 1, the drain/source voltage across memory cell MC4 rises with time, and current flows through memory cell MC4. This current depends strongly on the state of memory cell MC4 (programmed or erased memory cell). As a result, the total current flowing into the node cmi would depend on the logical state of memory cell MC4, which is the neighbor effect described in the background.

In contrast, as described above and appreciated from examining FIG. 5A, in the current folding scheme of the present invention, signals cmi and tref are at a stable voltage thought the sensing period. As a result, the voltage drop across memory cell MC4 would be relatively small, thereby significantly reducing or perhaps even eliminating the neighbor effect.

In summary, in brief and simplistic terms, the input cell current of a selected array cell of memory array 10 is to the input stage 16A. The input cell current is folded and used to discharge the input of a latch, the second stage 16B of sense amplifier 16. The latch provides an output digital signal (sa_out of third stage 16C) indicative of a logical content stored in the selected array cell. Folding the input cell current is carried out by a current mirror using an NMOS source-follower in input stage 16A.

The present invention may be useful in data flash applications as a method for little or no residual discharge for sequential readings. The invention may enable using a single reference cell per multiple sense amplifiers. The invention may be implemented for multilevel cell sensing.

The scope of the present invention includes both combinations and subcombinations of the features described hereinabove as well as modifications and variations thereof which would occur to a person of skill in the art upon reading the foregoing description and which are not in the prior art.

What is claimed is:

1. A method for sensing logical content stored in a memory cell, the method comprising:
inputting an input cell current of a selected array cell of a memory array to an input stage; and
folding said input cell current and using it to discharge an input of a latch, said latch providing an output digital signal indicative of a logical content stored in the selected array cell.

2. The method according to claim 1, wherein folding said input cell current is carried out by an NMOS current mirror using an NMOS source-follower in said input stage.

3. The method according to claim 2, comprising inputting bias voltages to said input stage so as to provide a constant current signal at drains of said NMOS current mirror, said current signal being defined by a folding ratio associated with said NMOS current mirror.

4. The method according to claim 1, comprising inputting a current signal cmi and a reference signal tref to said input stage, said input stage generating voltages V_latch_in and V_latch_in_b corresponding to the current signal cmi and the reference signal tref, respectively, said voltages being used to discharge the input of the latch.

5. The method according to claim 4, wherein said current signal cmi and reference signal tref define a differential current signal ‘I_cmi-I_tref’, and said voltages V_latch_in and V_latch_in_b define a differential voltage signal ‘V_latch_in-V_latch_in_b′, wherein said differential voltage signal is proportional to said differential current signal.

6. The method according to claim 5, wherein said I_cmi is larger than I_tref.

7. The method according to claim 5, wherein said I_cmi is smaller than I_tref.

8. The method according to claim 5, wherein said latch creates a logical differential signal based on said differential voltage signal, said logical differential signal being latched by a digital latching stage as a constant output latched signal until another latch signal is issued.

9. A system for sensing logical content stored in a memory cell, the system comprising:
a first stage comprising an analog input stage that receives an input cell current of a selected array cell of a memory array, said input stage comprising a current mirror operative to fold said input cell current, a second stage comprising an analog latch stage which generates a digital signal out of an analog signal coming from said input stage, and a third stage comprising a digital latching stage operative to output a digital signal indicative of a logical content stored in the selected array cell.

10. The system according to claim 9, wherein said input stage comprises an NMOS current mirror using an NMOS source-follower.

11. The system according to claim 9, wherein said second stage comprises a cross-coupled latch.

12. The system according to claim 9, wherein said digital latching stage comprises a set-reset flip flop.

13. The system according to claim 10, wherein bias voltages are input to said input stage so as to provide a constant current signal at drains of said NMOS current mirror, said current signal being defined by a folding ratio associated with said NMOS current mirror.

14. The system according to claim 9, wherein said first, second and third stages are part of a sense amplifier device.

15. The system according to claim 9, wherein said first and second stages are part of a sense amplifier device, and said third stage is external to said sense amplifier device.
